(19) United States
(12) Patent Application Publication
(10) Pub. No.: US 2022/0045078 A1
(43) Pub. Date: Feb. 10, 2022

(54) SEMICONDUCTOR STORAGE DEVICE AND MANUFACTURING METHOD THEREOF

(71) Applicant: Kioxia Corporation, Tokyo (JP)

(72) Inventor: Kazuhito FURUMOTO, Yokkaichi Mie (JP)

(21) Appl. No.: 17/190,868

(22) Filed: Mar. 3, 2021

(30) Foreign Application Priority Data
Aug. 5, 2020 (JP) 2020-133245

(51) Int. Cl. H01L 27/11568; H01L 27/11521

(52) U.S. Cl. CPC H01L 27/11568; H01L 27/11521

(57) ABSTRACT

A method of manufacturing a semiconductor storage device includes forming a coating layer covering a base layer, forming a recess that penetrates the coating layer and into the base layer, enlarging a portion of the recess to expose a portion of the coating layer in contact with the base layer, and etching a surface of the coating layer exposed inside the recess.

### CROSS-REFERENCE TO RELATED APPLICATION(S)

This application is based upon and claims the benefit of priority from Japanese Patent Application No. 2020-133245, filed on Aug. 5, 2020, the entire contents of which are incorporated herein by reference.

### FIELD

Embodiments described herein relate generally to a semiconductor storage device and a manufacturing method thereof.

### BACKGROUND

For example, in a semiconductor storage device such as NAND flash memory, a plurality of columnar bodies are embedded in a coating layer formed on a substrate. Examples of such “columnar bodies” include those that function as a plurality of memory cells arranged in series or those that function as contacts connected to a conductor layer.

### DESCRIPTION OF THE DRAWINGS

FIG. 1 is a cross-sectional view illustrating a configuration of a semiconductor storage device according to an embodiment.

FIG. 2 is a cross-sectional view illustrating a configuration of a semiconductor storage device according to a modification.

FIG. 3 is a cross-sectional view illustrating a method of manufacturing the semiconductor storage device illustrated in FIG. 1.

FIG. 4 is a cross-sectional view illustrating a method of manufacturing the semiconductor storage device illustrated in FIG. 1.

FIG. 5 is a cross-sectional view illustrating a method of manufacturing the semiconductor storage device illustrated in FIG. 1.

FIG. 6 is a cross-sectional view illustrating a method of manufacturing the semiconductor storage device illustrated in FIG. 1.

FIG. 7 is a cross-sectional view illustrating a method of manufacturing the semiconductor storage device illustrated in FIG. 1.

FIG. 8 is a cross-sectional view illustrating a method of manufacturing the semiconductor storage device illustrated in FIG. 1.

FIG. 9 is a view illustrating a shape of a recess.

FIG. 10 is a cross-sectional view illustrating the reason that the cross-sectional shape of the recess is partially reduced.

FIG. 11 is a cross-sectional view illustrating a method of manufacturing the semiconductor storage device illustrated in FIG. 1.

FIG. 12 is a cross-sectional view illustrating a method of manufacturing the semiconductor storage device illustrated in FIG. 1.

FIG. 13 is a cross-sectional view illustrating a method of manufacturing the semiconductor storage device illustrated in FIG. 1.

FIG. 14 is a cross-sectional view schematically illustrating the shape of the recess in the middle of manufacturing the semiconductor storage device illustrated in FIG. 1.

FIG. 15 is a cross-sectional view schematically illustrating the shape of a part of the semiconductor storage device illustrated in FIG. 1.

FIG. 16 is a cross-sectional view illustrating a configuration of a stepped portion in the semiconductor storage device illustrated in FIG. 1.

FIG. 17 is a cross-sectional view illustrating a method of manufacturing the semiconductor storage device illustrated in FIG. 1.

FIG. 18 is a cross-sectional view illustrating a method of manufacturing the semiconductor storage device illustrated in FIG. 1.

FIG. 19 is a cross-sectional view illustrating a method of manufacturing the semiconductor storage device illustrated in FIG. 1.

FIG. 20 is a cross-sectional view illustrating a method of manufacturing the semiconductor storage device illustrated in FIG. 1.

FIG. 21 is a cross-sectional view schematically illustrating the shape of the recess in the middle of manufacturing the semiconductor storage device illustrated in FIG. 1.

FIG. 22 is a cross-sectional view schematically illustrating the shape of a part of the semiconductor storage device illustrated in FIG. 16.

### DETAILED DESCRIPTION

In order to improve the performance of a semiconductor storage device, each columnar body may be formed such that the cross section of the columnar body perpendicular to the longitudinal direction thereof has a shape in which the size of a lower part in this longitudinal direction is suppressed in the degree of a decrease as compared with the size of an upper part.

Embodiments provide a semiconductor storage device having improved performance and a manufacturing method thereof.

In general, according to one embodiment, a semiconductor storage device includes a base layer, a coating layer configured to cover the base layer, and a columnar body penetrating the coating layer and connected to the base layer. In a portion of the columnar body near a boundary between the base layer and the coating layer, a cross section of the columnar body perpendicular to a longitudinal direction thereof has a shape that becomes larger as it approaches the boundary from a coating layer side.

Further, according to another embodiment, a method of manufacturing a semiconductor storage device includes forming a coating layer so as to cover a base layer, forming a recess that penetrates the coating layer and reaches a middle of the base layer, exposing a part of a portion of the coating layer that is in contact with the base layer by enlarging a portion of the recess that is formed in the base layer, and etching a surface of the coating layer exposed inside the recess.

Hereinafter, the present embodiment will be described with reference to the accompanying drawings. In order to facilitate understanding of the description, the same components will be designated by the same reference numerals as much as possible in each drawing, and duplicate descriptions thereof will be omitted.

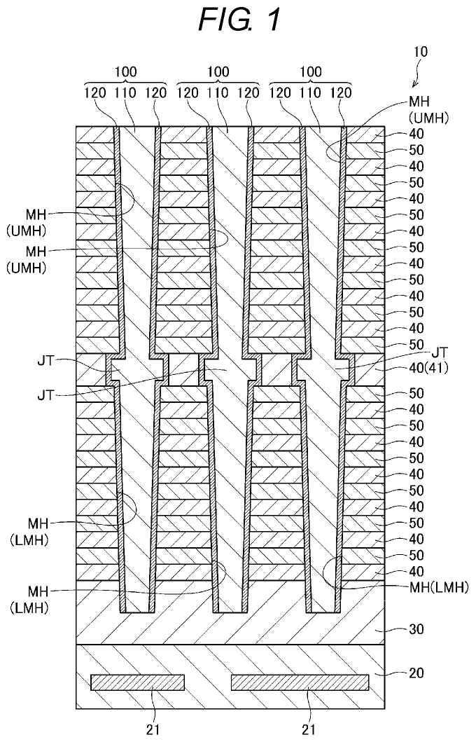

A semiconductor storage device 10 according to the present embodiment is a non-volatile storage device configured as NAND flash memory. In the semiconductor storage device 10, a plurality of memory cells are arranged three-dimensionally. A configuration of the semiconductor storage device 10 will be described with reference to FIG. 1.

The semiconductor storage device 10 includes an insulating layer 20, a semiconductor layer 30, and a plurality of columnar bodies 100.

The insulating layer 20 is, for example, a layer formed of an insulating material such as silicon oxide. A plurality of blocks designated by the reference numeral “21” in FIG. 1 schematically indicate circuit elements formed on a silicon substrate (not illustrated) or wirings connected to these circuit elements. These are provided as peripheral circuits for reading, writing, and erasing data for the memory cells. Hereinafter, these peripheral circuits are also referred to as “peripheral circuits 21”. The insulating layer 20 is a layer formed on the silicon substrate so as to cover the entirety of the peripheral circuits 21.

The semiconductor layer 30 is a layer that functions as a so-called “source line”. The semiconductor layer 30 is formed of, for example, a material containing silicon such as impurity-doped polycrystalline silicon. The semiconductor layer 30 covers the entire insulating layer 20 from above.

Furthermore, the term “above” as used herein means “above” when the semiconductor storage device 10 is viewed as illustrated in FIG. 1. Similarly, in the following description, the terms such as “above” and “below” may be used, but in every case, these terms are used to represent the direction when the semiconductor storage device 10 is viewed as illustrated in FIG. 1.

A plurality of insulating layers 40 and conductor layers 50 are alternately stacked on the semiconductor layer 30. The insulating layer 40 is a layer for electrical insulation between the respective conductor layers 50. The insulating layer 40 is formed of, for example, a material containing silicon oxide.

As will be described later, the conductor layer 50 is a layer connected to a gate of each transistor formed along the columnar body 100 to apply a voltage to this gate. The conductor layer 50 functions as a so-called “word line”. The conductor layer 50 is formed of, for example, a material containing tungsten.

The columnar body 100 is a rod-shaped member formed in a substantially cylindrical shape. The columnar body 100 is disposed such that the longitudinal direction thereof is along the direction in which the plurality of insulating layers 40 and conductor layers 50 are stacked. The columnar body 100 extends downward from the upper end of a portion where the plurality of insulating layers 40 and conductor layers 50 are stacked to a position in the middle of the semiconductor layer 30. That is, the columnar body 100 vertically penetrates the entirety of the insulating layers 40 and the conductor layers 50, and the lower end thereof is connected to the semiconductor layer 30 which is a base layer. In the semiconductor storage device 10, the plurality of columnar bodies 100 are provided.

Each columnar body 100 has a semiconductor 110 and a memory film 120. The semiconductor 110 is a portion that occupies most of the columnar body 100, and is formed of, for example, a material made of amorphous silicon. Another layer made of, for example, an insulating material may be formed inside the columnar body 100.

The memory film 120 is a film that covers the entire side surface of the semiconductor 110. The memory film 120 is formed by stacking a plurality of films, but, in FIG. 1, the entirety of the films is depicted as a single memory film 120. The plurality of films constituting the memory film 120 include a tunnel insulating film, a charge storage film, and a block insulating film in this order from the inside thereof. Each of the stacked conductor layers 50 is connected to the block insulating film formed on the outermost side.

The inside of a portion of the columnar body 100 to which each conductor layer 50 is connected functions as a transistor. That is, in the semiconductor storage device 10, a plurality of transistors are connected in series along the longitudinal direction of each columnar body 100. Each conductor layer 50 is connected to a gate of each transistor via the tunnel insulating film and the charge storage film. The semiconductor 110 inside the transistor functions as a channel of this transistor.

Transistors arranged in series as described above along the longitudinal direction of the columnar body 100 function as memory cells for storing data. Further, the transistors formed at both ends of the plurality of memory cells arranged in series function as select transistors for controlling the current flowing through the channel of each memory cell.

Charges are stored in the charge storage film of the memory film 120 as a voltage is applied to the conductor layer 50. The amount of charges stored in the charge storage layer corresponds to data stored in the memory cell. The memory cell may be of a charge trap type using, for example, a silicon nitride film as the charge storage layer, or may be of a floating gate type using, for example, a silicon film as the charge storage layer.

At the lower side end of the columnar body 100, the memory film 120 is removed, and the lower end of the semiconductor 110 is connected to the semiconductor layer 30. Thus, the semiconductor layer 30 which functions as a source line and the channel of each transistor are electrically connected to each other. Furthermore, the upper end of the semiconductor 110 is connected to a bit line via a contact (not illustrated).

Furthermore, various modes which have already been known may be adopted as configurations of the peripheral circuits for implementing reading and writing of data to and from each memory cell and specific operations thereof. Therefore, a further specific description will be omitted.

A plurality of concave memory holes (hereinafter also referred to as “MH”) are formed in the insulating layers 40 and the conductor layers 50 stacked one above another so as to recede from above to below, and each columnar body 100 is formed inside the MH.

By the way, the number of insulating layers 40 and conductor layers 50 stacked on the upper surface of the semiconductor layer 30 is actually larger than the number of stacked layers illustrated in FIG. 1. In such a configuration, the ratio of the total length to the inner diameter of the MH is very large, so that it is difficult to form the entire MH in one processing. Thus, when the semiconductor storage device 10 is manufactured, the formation of the MH is divided into two times. A lower portion of the MH formed by a first processing is also referred to below as “LMH” as an abbreviation for “Lower Memory Hole”. Further, an upper portion of the MH formed by a second processing is also referred to below as “UMH” as an abbreviation for “Upper Memory Hole”. Furthermore, the formation of the MH may be divided into three or more times.

As illustrated in FIG. 1, a joint portion (hereinafter, also referred to as “JT”) which interconnects the LMH and the UMH is formed in a portion between the LMH and the UMH. In the present embodiment, the JT is formed inside the insulating layer 40 stacked at a substantially center position along the vertical direction. The insulating layer 40 is also referred to below as an “insulating layer 41”. Although the insulating layer 41 is formed as a layer thicker than the other insulating layers 40, it may be formed as a layer having the same thickness as the other insulating layers 40. Further, in the present embodiment, the height position of each of the upper end and the lower end of the JT is the same as the height position of each of the upper end and the lower end of the insulating layer 41. Instead of this mode, the height position of the upper end of the JT may be different from the height position of the upper end of the insulating layer 41, or the height position of the lower end of the JT may be different from the height position of the lower end of the insulating layer 41.

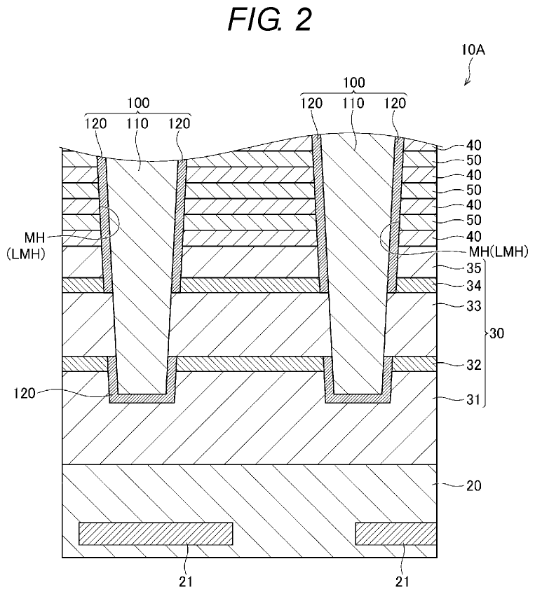

Furthermore, details of the configuration of the semiconductor storage device 10 may be different from that illustrated in FIG. 1. FIG. 2 illustrates a configuration of a semiconductor storage device 10A according to a modification of the present embodiment as a schematic cross-sectional view.

In this modification, the semiconductor layer 30 has a first semiconductor layer 31, a second semiconductor layer 33, and a third semiconductor layer 35. The first semiconductor layer 31 is a layer formed at the lowermost position, the second semiconductor layer 33 is a layer formed above the first semiconductor layer 31, and the third semiconductor layer 35 is formed on the uppermost side. All of these are formed of, for example, a material containing silicon such as impurity-doped polycrystalline silicon.

An insulating layer 32 is formed between the first semiconductor layer 31 and the second semiconductor layer 33. Similarly, an insulating layer 34 is formed between the second semiconductor layer 33 and the third semiconductor layer 35. Both the insulating layers 32 and 34 are formed of, for example, a material having an insulating property such as a material containing silicon oxide.

In this modification, the memory film 120 is removed from a portion of the side surface of the semiconductor 110 facing the second semiconductor layer 33. Thus, the semiconductor 110 and the second semiconductor layer 33 are electrically connected in this portion. Furthermore, a portion of the semiconductor 110, other than this portion, which includes the lower side end, is covered with the memory film 120.

In the semiconductor storage device 10A having such a configuration, only the second semiconductor layer 33 of the semiconductor layer 30 functions as a source line connected to the channel of each transistor. Even in a mode in which the entire semiconductor layer 30 is not a layer formed of a single material, but is partially provided with a layer made of any other material (e.g., the insulating layers 32 and 34) as in this modification, the same manufacturing method as that to be described later may be adopted.

Hereinafter, a method of manufacturing the semiconductor storage device 10 according to the present embodiment will be described.

<First Stacking Step>

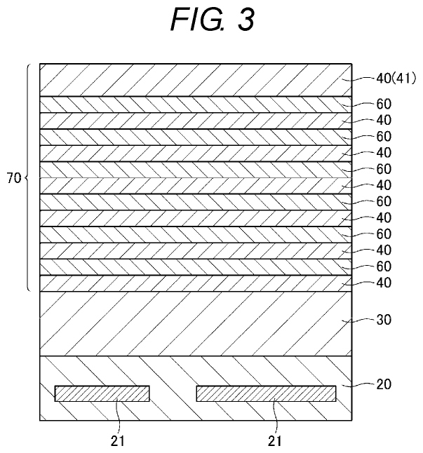

In a first stacking step, after the peripheral circuit 21 is formed on a silicon substrate (not illustrated), the insulating layer 20 covering the peripheral circuit 21 and the semiconductor layer 30 covering the insulating layer 20 are formed in this order. After that, a plurality of insulating layers 40 and sacrificial layers 60 are alternately formed so as to cover the semiconductor layer 30. FIG. 3 illustrates a state where the first stacking step is completed.

The sacrificial layer 60 is a layer that is replaced with the conductor layer 50 in a later replacement step, and is formed of, for example, a material containing silicon nitride. In the first stacking step, each of the above layers including the sacrificial layer 60 is formed by, for example, CVD.

Furthermore, what is formed in the first stacking step is a portion from the insulating layer 20 to the insulating layer 41 of the semiconductor storage device 10 illustrated in FIG. 1. A portion on the insulating layer 41 is formed in a second stacking step to be described later. The semiconductor layer 30 formed in the first stacking step corresponds to the “base layer”. Further, the entirety of the insulating layers 40 and the sacrificial layers 60 alternately formed above the semiconductor layer 30 correspond to a “coating layer” covering the base layer. The entirety of the insulating layers 40 and the sacrificial layers 60 formed in the first stacking step are also referred to below as a “coating layer 70”. In this way, the first stacking step is a step of forming the coating layer 70 so as to cover the semiconductor layer 30 which is the base layer.

<First Recess Forming step>

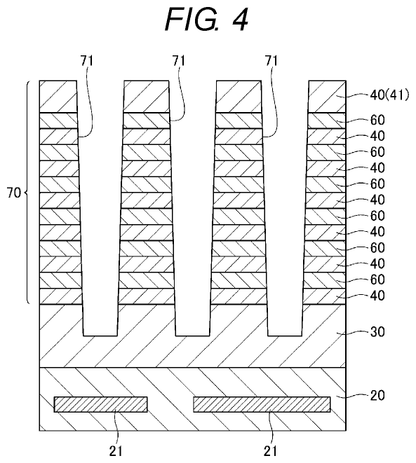

In a first recess forming step performed after the first stacking step, a recess 71 which becomes an LMH later is formed by, for example, Reactive Ion Etching (RIE). FIG. 4 illustrates a state where the first recess forming step is completed.

The recess 71 is formed from the surface of the insulating layer 41 to a position in the middle of the semiconductor layer 30, that is, a position lower than the upper end and higher than the lower end of the semiconductor layer 30. The recess 71 has a substantially circular cross section perpendicular to the longitudinal direction thereof. The longitudinal direction of the recess 71 is perpendicular to each layer such as the semiconductor layer 30 or the insulating layer 40. In this way, the first recess forming step is a step of forming the recess 71 that penetrates the coating layer 70 and reaches the middle of the semiconductor layer 30 which is the base layer.

In the first recess forming step, the semiconductor layer 30 which is the base layer functions as an etching stopper when forming the recess 71. When selectivity for the base layer is not sufficient, there is a possibility that the recess 71 penetrates the semiconductor layer 30 and reaches the insulating layer 20 and a part of the peripheral circuit 21 is etched. Thus, silicon which is a material capable of providing sufficient selectivity is used as a material for the semiconductor layer 30 so as to absorb variation in the etching rate when each recess 71 is formed and to ensure that the formation of the recess 71 is reliably completed at a position in the middle of the semiconductor layer 30.

At the time when the first recess forming step is completed, a mask material (not illustrated) remains on the surface of the coating layer 70. This mask material is composed of, for example, a carbon film used for RIE. This mask material is removed by an ashing treatment. In order to clean the inner surface of the recess 71 after the ashing treatment and before shifting to a sacrificial material embedding step to be described below, wet etching using diluted hydrofluoric acid (DHF) is performed. A step of performing wet etching in this way corresponds to an “inner peripheral surface removing step” to be described later in detail.

<Sacrificial Material Embedding Step>

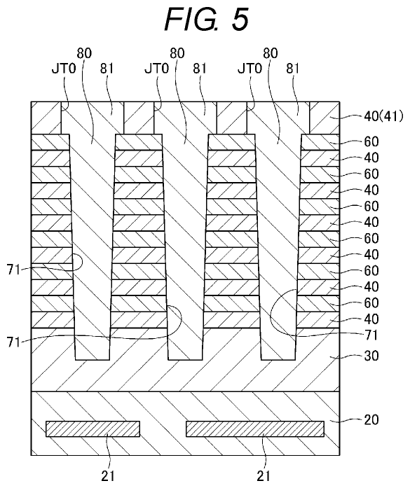

In a sacrificial material embedding step performed after the first recess forming step, a sacrificial material 80 is embedded inside the recess 71. FIG. 5 illustrates a state where the sacrificial material embedding step is completed.

Examples of the sacrificial material 80 include a material containing silicon such as amorphous silicon. The sacrificial material 80 is embedded by, for example, CVD. Furthermore, in the middle phase of embedding the sacrificial material 80 inside the recess 71, a processing is performed to enlarge the inner diameter of a portion of the recess 71 that is formed in the insulating layer 41 by, for example, isotropic etching. In this way, the portion of the recess 71 having the enlarged inner diameter is also referred to below as an “enlarged diameter portion JT0”. The enlarged diameter portion JT0 is a portion where the JT is formed later. In the sacrificial material embedding step, the sacrificial material 80 is also embedded in the entire inside of the enlarged diameter portion JT0. A portion of the sacrificial material 80 embedded inside the enlarged diameter portion JT0 is also referred to below as a “sacrificial material 81”.

<Second Stacking Step>

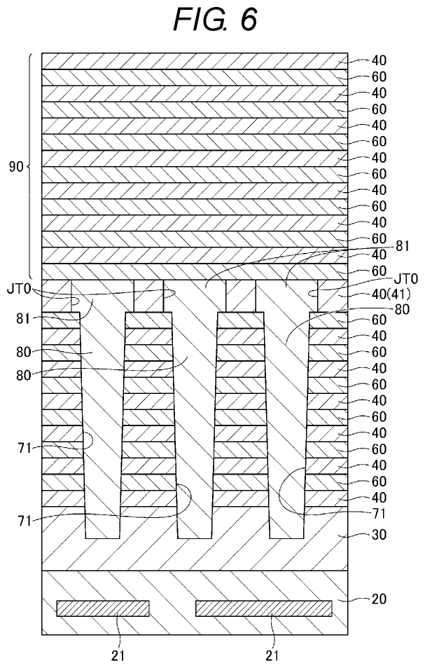

Ina second stacking step performed after the sacrificial material embedding step, a plurality of sacrificial layers 60 and insulating layers 40 are alternately formed so as to cover the insulating layer 41 in which the sacrificial material 81 is formed. FIG. 6 illustrates a state where the second stacking step is completed. Similar to the first stacking step, in the second stacking step, each of the above layers is formed by, for example, CVD. What is formed in the second stacking step is a portion of the semiconductor storage device 10 illustrated in FIG. 1 on the insulating layer 41.

The sacrificial material 81 previously formed in the enlarged diameter portion JT0 of the insulating layer 41 corresponds to the “base layer” similarly to the semiconductor layer 30 described above. The entirety of the insulating layers 40 and the sacrificial layers 60 alternately formed above the sacrificial material 81 correspond to a “coating layer” covering the base layer. The entirety of the insulating layers 40 and the sacrificial layers 60 formed in the second stacking step are also referred to below as a “coating layer 90”. In this way, the second stacking step is a step of forming the coating layer 90 so as to cover the sacrificial material 81 which is the base layer.

<Second Recess Forming Step>

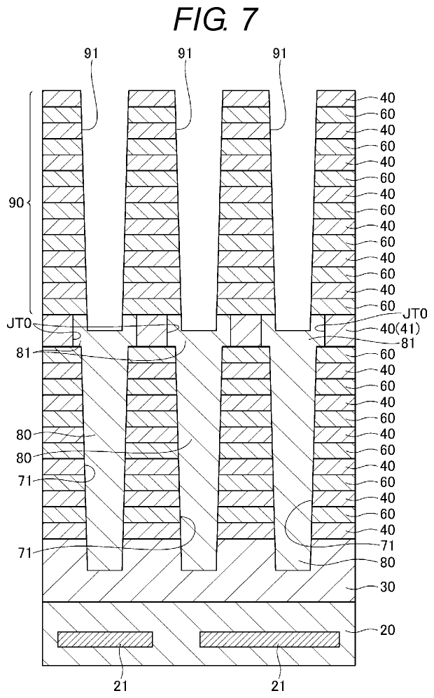

In a second recess forming step performed after the second stacking step, a recess 91 which becomes an UMH later is formed by, for example, RIE similarly to the first recess forming step. FIG. 7 illustrates a state where the second recess forming step is completed.

The recess 91 is formed from the surface of the insulating layer 40 formed on the uppermost side in the second stacking step to a position in the middle of the sacrificial material 81, that is, a position lower than the upper end and higher than the lower end of the sacrificial material 81. The recess 91 has a substantially circular cross section perpendicular to the longitudinal direction thereof similarly to the recess 71 formed in the first recess forming step. The longitudinal direction of the recess 91 is perpendicular to each layer such as the semiconductor layer 30 or the insulating layer 40. Further, the center axis of the recess 91 substantially coincides with the center axis of the recess 71. In this way, the second recess forming step is a step of forming the recess 91 that penetrates the coating layer 90 and reaches the middle of the sacrificial material 81 which is the base layer.

In the second recess forming step, the sacrificial material 81 which is the base layer functions as an etching stopper when forming the recess 91. When selectivity for the base layer is not sufficient, the recess 91 penetrates the sacrificial material 81. At this time, when the center axis of the recess 91 does not coincide with the center axis of the recess 71 located on the lower side, there is a possibility that a part of the coating layer 70 below the sacrificial material 81 is etched. Thus, silicon which is a material capable of providing sufficient selectivity is used as a material for the sacrificial material 81 so as to absorb variation in the etching rate when each recess 91 is formed and to ensure that the formation of the recess 91 is reliably completed at a position in the middle of the sacrificial material 81.

At the time when the second recess forming step is completed, a register film (not illustrated) remains on the surface of the coating layer 90. This register film is removed by an ashing treatment. In order to clean the inner surface of the recess 91 after the ashing treatment and before shifting to a sacrificial material removing step to be described below, wet etching using diluted hydrofluoric acid is performed.

<Sacrificial Material Removing Step>

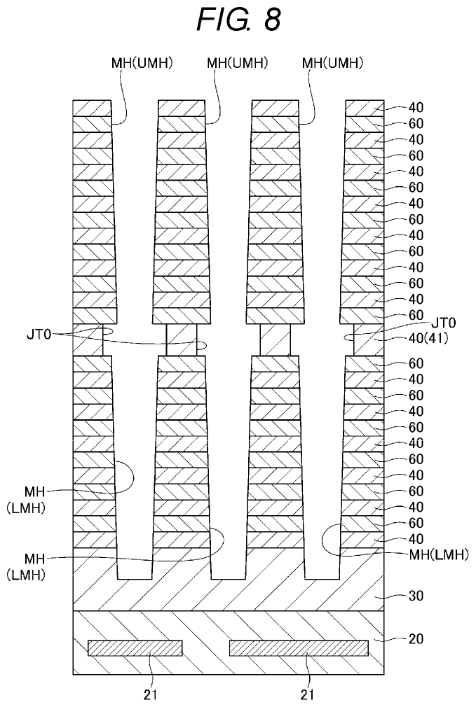

In a sacrificial material removing step performed after the second recess forming step, the sacrificial material 80 embedded inside the enlarged diameter portion JT0 or the recess 71 is removed by, for example, wet etching. FIG. 8 illustrates a state where the sacrificial material removing step is completed. When the sacrificial material removing step is completed, a plurality of MHs are formed so as to penetrate the entirety of the insulating layers 40 and the sacrificial layers 60 alternately formed on the semiconductor layer 30. Each recess 71 formed in the first recess forming step becomes an LMH, and each recess 91 formed in the second recess forming step becomes an UMH.

<Columnar Body Forming Step>

In a columnar body forming step performed after the sacrificial material removing step, a block insulating film, a charge storage film, and a tunnel insulating film are formed in this order on the inner peripheral surface of the MH, so that the memory film 120 illustrated in FIG. 1 is formed. After that, the semiconductor 110 is further formed inside the memory film 120, so that the columnar body 100 illustrated in FIG. 1 is formed. Both the memory film 120 and the semiconductor 110 are formed by, for example, CVD.

<Replacement Step>

In a replacement step performed after the columnar body forming step, the plurality of previously formed sacrificial layers 60 are replaced with the conductor layers 50. Although not illustrated, in the replacement step, slits are formed so as to divide the entirety of the alternately formed insulating layers 40 and sacrificial layers 60, and all of the sacrificial layers 60 are removed by wet etching through these slits. After that, a metal material containing, for example, tungsten is embedded in the space where the sacrificial layer 60 is formed, so that the conductor layer 50 is formed. The metal material is embedded by, for example, CVD. After the replacement step is performed, for example, a stepped portion to be described later is formed, and the semiconductor storage device 10 illustrated in FIG. 1 is completed.

By the way, in order to fully exhibit the performance of the semiconductor storage device 10, the diameter of the columnar body 100 may be substantially uniform in the whole from the upper end to the lower end of at least the range that functions as a transistor of the columnar body 100. Furthermore, “the range that functions as a transistor” in the above is the range of a portion of the columnar body 100 that penetrates the insulating layers 40 (excluding the insulating layer 41) and the conductor layers 50.

When the diameter of the columnar body 100 is too small in a portion, the electrical performance of each memory cell will be uneven. Further, when the inner diameter of the MH is too small in a portion, for example, there is a possibility that this portion is blocked in the sacrificial material embedding step, and the sacrificial material 80 is not sufficiently embedded in the whole. Further, there is a possibility that this portion is blocked even in the replacement step and the metal material is not sufficiently embedded in the whole.

Accordingly, for each recess 71 formed in the first recess forming step, the shape of the cross section perpendicular to the longitudinal direction thereof may be uniform over at least the entire range penetrating the coating layer 70 regardless of the height position. The same is also applied to each recess 91 formed in the second recess forming step. However, due to the characteristics of anisotropic etching by RIE, it is difficult to make the shape of this cross section completely uniform. As exaggeratedly expressed in FIG. 4, the shape of the cross section of the recess 71 tends to gradually become smaller from the upper side to the lower side.

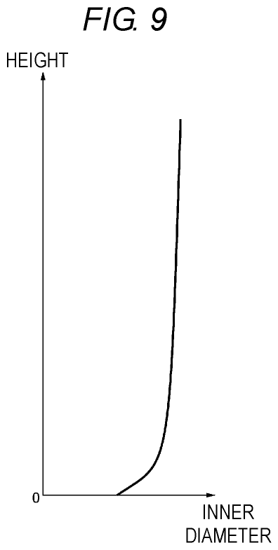

FIG. 9 is a graph illustrating an example of a relationship between the height position (vertical axis) of the recess 71 and the inner diameter (horizontal axis) of the recess 71 at each position. The height position where the value on the vertical axis in FIG. 9 is zero is the boundary position between the lowermost insulating layer 40 and the semiconductor layer 30, that is, the lower end position of the coating layer 70.

As in the example illustrated in FIG. 9, the inner diameter of the recess 71 gradually decreases from the upper side to the lower side, but tends to decrease sharply near the lower end position of the coating layer 70. Such a problem may also equally occur in each recess 91 formed in the second recess forming step.

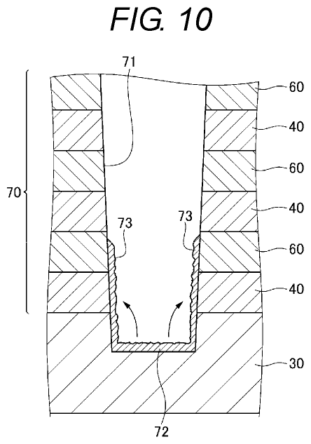

The reason that the inner diameter of the recess 71 tends to be particularly small near the lower end position of the coating layer 70 will be described with reference to FIG. 10. FIG. 10 illustrates a cross section of the semiconductor layer 30 and a nearby portion thereof at the time in the middle of performing the first recess forming step.

A fluorocarbon based gas is generally used as an etching gas for RIE in the first recess forming step. When the sacrificial layer 60 is etched, carbon contained in the fluorocarbon based gas reacts with nitrogen in silicon nitride which is the material of the sacrificial layer 60, and is discharged to the outside as a gas. Further, when the insulating layer 40 is etched, carbon contained in the fluorocarbon-based gas reacts with oxygen in silicon oxide which is the material of the insulating layer 40, and is also discharged to the outside as a gas.

As described above, silicon is used as the material of the semiconductor layer 30 which is the base layer in order to increase selectivity at the time of etching. This material does not contain elements that react with carbon contained in the fluorocarbon based gas, that is, oxygen or nitrogen. Thus, carbon contained in the fluorocarbon based gas is precipitated when the semiconductor layer 30 is etched, and is deposited on a bottom portion of the recess 71 as in the portion designated by the reference numeral “72” in FIG. 10. The carbon deposited in this way is also referred to below as a “deposit 72”.

Ions reach the deposit 72 during implementation of RIE. Therefore, a part of the deposit 72 is spattered by these ions, and is deposited on the inner peripheral surface near the lower end portion of the recess 71 as in the portion designated by the reference numeral “73” in FIG. 10. That is, a part of the deposit 72 is re-sputtered and deposited on the inner peripheral surface of the recess 71. The carbon deposited in this way is also referred to below as a “re-sputtered material 73”.

A portion of the inner peripheral surface of the recess 71 covered with the re-sputtered material 73 is difficult for ions to reach and therefore, is deteriorated in the etching rate by RIE. As a result, the inner diameter of the recess 71 gradually decreases from the upper side to the lower side, and particularly sharply decreases near the lower end position of the coating layer 70. The same is also applied to each recess 91 formed in the second recess forming step, and the inner diameter of the recess 91 gradually decreases from the upper side to the lower side, and particularly sharply decreases near the lower end position of the coating layer 90.

Accordingly, when manufacturing the semiconductor storage device 10, in addition to the respective steps described so far, the following steps are also performed to enlarge the inner diameter of the recess 71 near the lower end portion of the coating layer 70 or the inner diameter of the recess 91 near the lower end portion of the coating layer 90 as compared with the related art.

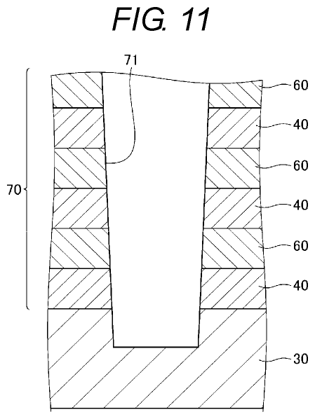

A step of enlarging the inner diameter of the recess 71 near the lower end portion of the coating layer 70 and making the distribution of this inner diameter along the vertical direction close to even distribution will be described. FIG. 11 illustrates a state immediately after the first recess forming step is completed as in FIG. 4. In the cross-sectional view of FIG. 11, the inner peripheral surface of the recess 71 is illustrated in a simplified manner so as to be linear. However, in reality, as in the example illustrated in FIG. 9, the inner diameter of the recess 71 near the lower end portion of the coating layer 70 sharply decreases as it approaches this lower end portion.

<Base Layer Diameter Enlarging Step>

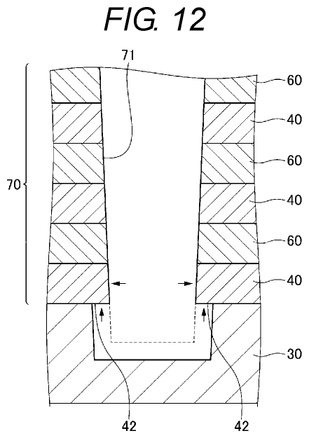

After the first recess forming step is completed and the asking treatment is performed as described above, a base layer diameter enlarging step and an inner peripheral surface removing step are performed in this order before the sacrificial material embedding step. In the base layer diameter enlarging step, a processing is performed to enlarge the inner diameter of a portion of the recess 71 that is formed in the semiconductor layer 30 which is the base layer as compared with the other portion. FIG. 12 illustrates a state where the base layer diameter enlarging step is completed. Furthermore, what is illustrated by the dotted line in FIG. 12 is the initial shape of the inner surface of the recess 71 at the time before the base layer diameter enlarging step is performed.

In the base layer diameter enlarging step, etching is performed using a room temperature choline aqueous solution (R-TMY). Thus, only a portion of the inner surface of the recess 71 in the semiconductor layer 30 is selectively removed. As a result, the portion of the recess 71 formed in the semiconductor layer 30 is enlarged as compared with the other portion.

When the base layer diameter enlarging step is performed, a part of a portion of the coating layer 70 that is in contact with the semiconductor layer 30 which is the base layer is exposed to the inner space of the recess 71. In FIG. 12, the reference numeral “42” is given to the exposed portion. This portion is also referred to below as an “exposed portion 42”.

In this way, the base layer diameter enlarging step is a step of exposing a portion of the coating layer 70 that is in contact with the semiconductor layer 30 which is the base layer by enlarging a portion of the recess 71 that is formed in the semiconductor layer 30.

<Inner Peripheral Surface Removing Step>

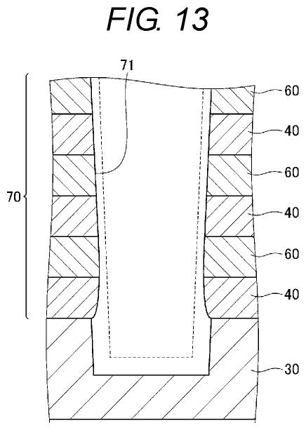

When the base layer diameter enlarging step is completed, an inner peripheral surface removing step is performed. The inner peripheral surface removing step is a step performed to clean the inner surface of the recess 71. As described above, wet etching using diluted hydrofluoric acid is performed on the inner surface of the recess 71. FIG. 13 illustrates a state where the inner peripheral surface removing step is completed. Furthermore, what is illustrated by the dotted line in FIG. 13 is the initial shape of the inner surface of the recess 71 at the time before the base layer diameter enlarging step or the inner peripheral surface removing step is performed. In this way, the inner peripheral surface removing step is a step of etching the surface of the coating layer 70 exposed inside the recess 71.

In the inner peripheral surface removing step, the entire inner surface of the recess 71 is exposed to diluted hydrofluoric acid. At this time, in each of the insulating layers 40 and the sacrificial layers 60 constituting the coating layer 70, only aside surface portion exposed toward the recess 71 is exposed to diluted hydrofluoric acid, and this portion is removed. However, in the insulating layer 40 formed at the lowermost position in the coating layer 70, that is, directly above the semiconductor layer 30, not only the side surface portion exposed toward the recess 71 but also the exposed portion 42 on the lower surface side are exposed to diluted hydrofluoric acid as indicated by the arrows in FIG. 12. Therefore, in the inner peripheral surface removing step, a portion of the inner peripheral surface of the recess 71 near the lower end portion of the coating layer 70 is removed more than the other portion.

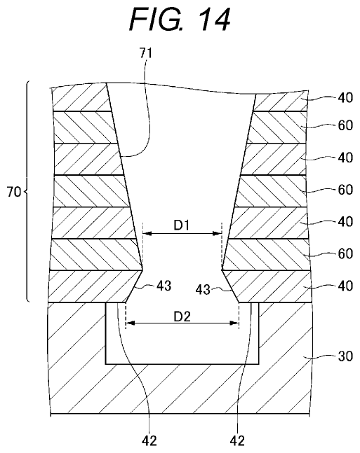

FIG. 14 schematically illustrates the shape of the recess 71 at the time when the inner peripheral surface removing step is completed. As illustrated in FIG. 14, the inner diameter of the recess 71 in the cross section perpendicular to the longitudinal direction of the recess 71 becomes smaller from the upper side to the lower side, and in the smallest portion, this inner diameter becomes D1. However, the inner diameter of the recess 71 becomes larger toward the lower side in a portion on the further lower side of this portion, that is, in the portion designated by the reference numeral “43” in FIG. 14, and the inner diameter of the recess 71 becomes D2 larger than D1 at the lower end of the coating layer 70. This is because a portion near the lower end portion of the coating layer 70 is removed more than the other portion as described above.

Furthermore, in FIG. 14, the inner diameter of the recess 71 is the smallest D1 at the boundary position between the lowermost insulating layer 40 of the coating layer 70 and the sacrificial layer 60 directly on the insulating layer 70. However, since the position of the portion where the inner diameter of the recess 71 becomes the smallest changes according to, for example, the size of the exposed portion 42, the position may be different from the example of FIG. 14.

In this way, after the first recess forming step is completed, the base layer diameter enlarging step and the inner peripheral surface removing step are sequentially executed before the sacrificial material embedding step is performed. In the base layer diameter enlarging step, the inner diameter of a portion of the recess 71 that is formed in the semiconductor layer 30 which is the base layer is enlarged, and the exposed portion 42 is formed in the coating layer 70. In the subsequent inner peripheral surface removing step, the surface of the coating layer 70 exposed inside the recess 71 is etched, and a portion near the lower end portion of the coating layer 70 is removed more than the other portion. Thus, the inner diameter of the recess 71 near the lower end portion of the coating layer 70 is enlarged, so that the distribution of the inner diameter of the recess 71 may be made close to even distribution and the performance of the semiconductor storage device 10 may be fully exhibited.

Furthermore, immediately before the base layer diameter enlarging step is performed, wet etching or RIE using diluted hydrofluoric acid may be performed on the inner surface of the recess 71. Thus, an oxide film formed on the inner surface of the semiconductor layer 30 is removed in advance, so that etching using a choline aqueous solution may be appropriately performed in the subsequent base layer diameter enlarging step.

The base layer diameter enlarging step and the inner peripheral surface removing step as described above are also executed at the timing not only after the first recess forming step is completed but also after the second recess forming step is completed and before the sacrificial material removing step is performed. Although not illustrated, in the base layer diameter enlarging step after the second recess forming step is completed, a processing is performed to enlarge the inner diameter of a portion of the recess 91 that is formed in the sacrificial material 81 which is the base layer as compared with the other portion. Thus, a part of a portion of the coating layer 90 that is in contact with the sacrificial material 81 is exposed to the inner space of the recess 91.

In the subsequent inner peripheral surface removing step, wet etching using diluted hydrofluoric acid is performed on the surface of the coating layer 90 exposed inside the recess 91. Thus, a portion of the inner peripheral surface of the recess 91 near the lower end portion of the coating layer 90 is removed more than the other portion. As a result, the inner diameter of the recess 91 near the lower end portion of the coating layer 90 is enlarged similarly to the shape of the recess 71 illustrated in FIG. 14. As a result, the distribution of the inner diameter of the recesses 91 may be made close to even distribution, and the performance of the semiconductor storage device 10 may be fully exhibited.

Even in this case, immediately before the base layer diameter enlarging step is performed, wet etching or RIE using diluted hydrofluoric acid may be performed on the inner surface of the recess 91. Thus, an oxide film formed on the inner surface of the sacrificial layer 81 is removed in advance, so that etching may be appropriately performed on the sacrificial layer 81 in the subsequent base layer diameter enlarging step.

As described above, when manufacturing the semiconductor storage device 10, a step of forming a coating layer so as to cover a base layer (the first stacking step and the second stacking step), a step of forming a recess that penetrates the coating layer and reaches the middle of the base layer (the first recess forming step and the second recess forming step), a step of exposing a part of a portion of the coating layer that is in contact with the base layer by enlarging a portion of the recess that is formed in the base layer (the base layer diameter enlarging step), and a step of etching the surface of the coating layer exposed inside the recess (the inner peripheral surface removing step) are executed respectively. Thus, the distribution of the inner diameter of the recess 71 and the distribution of the inner diameter of the recess 91 may be made close to even distribution, and the performance of the semiconductor storage device 10 may be improved.

Both the semiconductor layer 30 and the sacrificial material 81 which are the base layer are layers formed of a material containing silicon. Further, in the base layer diameter enlarging step, etching using a choline aqueous solution is performed on this base layer formed of a material containing silicon. Thus, the inner diameter of a portion of the recess 71 that is formed in the semiconductor layer 30 or the inner diameter of a portion of the recess 91 that is formed in the sacrificial material 81 may be reliably enlarged.

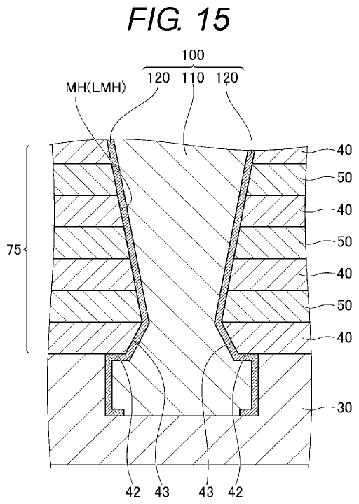

FIG. 15 schematically illustrates a configuration of the completed semiconductor storage device 10 near the lower end portion of the columnar body 100. The columnar body 100 is formed inside the recess 71 having a shape as illustrated in FIG. 14.

The plurality of insulating layers 40 and conductor layers 50 are alternately stacked on the semiconductor layer 30 as described with reference to FIG. 1. The entirety of the insulating layers 40 and the conductor layers 50 stacked in this way is also referred to below as a “coating layer 75”. The coating layer 75 may be said to be a layer that covers the semiconductor layer 30 which is the base layer.

As illustrated in FIG. 15, in a portion of the columnar body 100 near the boundary between the semiconductor layer 30 which is the base layer and the coating layer 75 (the portion designated by the reference numeral 43), the shape of the cross section of the columnar body 100 perpendicular to the longitudinal direction thereof becomes larger as it approaches the above boundary from the coating layer 75 side (that is, the upper side). As a result, the diameter of the columnar body 100 is substantially uniform in a portion of the columnar body 100 that penetrates the coating layer 75, so that the semiconductor storage device 10 may sufficiently exhibit the performance thereof.

Although not illustrated, the same may be applied to a portion of the columnar body 100 on the sacrificial material 81. When the entirety of the insulating layers 40 and the conductor layers 50 stacked on the sacrificial material 81 is again defined as the “coating layer 75”, the sacrificial material 81 which is the base layer is covered with the coating layer 75 from the upper side thereof. In a portion of the columnar body 100 near the boundary between the sacrificial material 81 which is the base layer and the coating layer 75, the shape of the cross section of the columnar body 100 perpendicular to the longitudinal direction thereof becomes larger as it approaches the above boundary from the coating layer 75 side (that is, the upper side). In this way, the diameter of the columnar body 100 is substantially uniform in a portion of the columnar body 100 that penetrates the coating layer 75, so that the semiconductor storage device 10 may sufficiently exhibit the performance thereof.

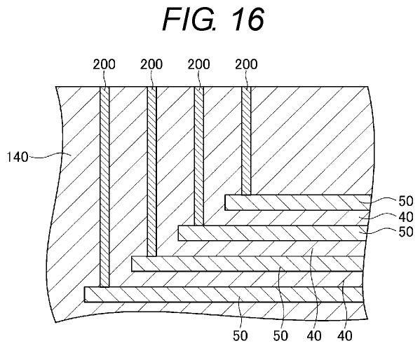

FIG. 16 schematically illustrates the cross section of a portion of the semiconductor storage device 10 that is different from the portion illustrated in FIG. 1. Each conductor layer 50 illustrated in FIG. 16 is drawn out in a step shape along a direction parallel to the surface of the semiconductor layer 30 from a portion where the plurality of columnar bodies 100 are formed as illustrated in FIG. 1. A portion of the semiconductor storage device 10 illustrated in FIG. 16 is also referred to below as a “stepped portion”. Furthermore, in the stepped portion, the insulating layer 40 is formed between the conductor layers 50 adjacent to each other. Further, an insulating layer 140 made of the same material as the insulating layer 40 is formed around a contact 200 to be described later.

In the stepped portion, the lower end of the contact 200 is connected to the upper surface of each of the conductor layers 50 drawn out in a step shape. The contact 200 is, for example, a rod-shaped member formed of a metal such as tungsten. The contact 200 electrically connects a wiring layer (not illustrated) formed on the semiconductor storage device 10 and each of the conductor layers 50 to each other.

A method of forming the contact 200 at the time of manufacturing the semiconductor storage device 10 will be described.

<Stepped Portion Forming Step>

After the replacement step described above is performed, etching by RIE and slimming of a resist are alternately repeated with respect to the coating layer 75 in which the insulating layers 40 and the conductor layers 50 are alternately stacked, so that the coating layer 75 is processed in a step shape. When the stepped portion forming step is performed, the respective conductor layers 50 have a step shape as illustrated in FIG. 16. Furthermore, since a known step may be used as such a stepped portion forming step, descriptions and illustrations of a specific process are omitted.

<Third Stacking Step>

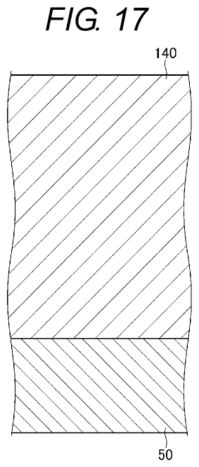

In a third stacking step performed after the stepped portion forming step, the insulating layer 140 is formed so as to cover the entire upper surface of the coating layer 75 processed in a step shape. In the third stacking step, after the insulating layer 140 is formed by, for example, CVD, the entire surface thereof is flattened. FIG. 17 illustrates a portion of the conductor layer 50 that is drawn out in a step shape and the insulating layer 140 formed so as to cover this portion of the conductor layer 50 from the upper side.

The conductor layer 50 corresponds to the “base layer”, and the insulating layer 140 corresponds to the “coating layer” covering the base layer. The third stacking step may be said to be a step of forming the insulating layer 140 which is the coating layer so as to cover the conductor layer 50 which is the base layer.

<Third Recess Forming Step>

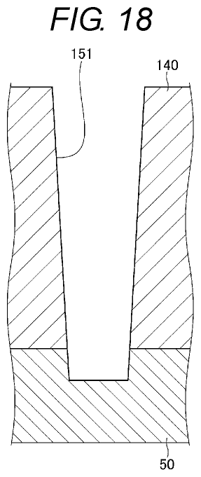

In a third recess forming step performed after the third stacking step, a recess 151 for embedding the contact 200 later is formed by, for example, RIE. FIG. 18 illustrates a state where the third recess forming step is completed in the portion illustrated in FIG. 17.

The recess 151 is formed from the surface of the insulating layer 140 to a position in the middle of the conductor layer 50, that is, a position lower than the upper end and higher than the lower end of the conductor layer 50. The recess 151 has a substantially circular cross section perpendicular to the longitudinal direction thereof. The longitudinal direction of the recess 151 is perpendicular to each layer such as the semiconductor layer 30 or the conductor layer 50. In this way, the third recess forming step is a step of forming the recess 151 that penetrates the insulating layer 140 which is a coating layer and reaches the middle of the conductor layer 50 which is the base layer.

At the time when the third recess forming step is completed, a register film (not illustrated) remains on the surface of the insulating layer 140. This register film is removed by an ashing treatment.

<Base Layer Diameter Enlarging Step>

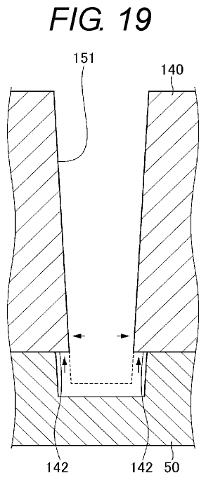

After the third recess forming step is completed and the ashing treatment is performed as described above, a base layer diameter enlarging step which is equal to that described with reference to FIG. 12 is performed. In the base layer diameter enlarging step herein, a processing is performed to enlarge the inner diameter of a portion of the recess 151 that is formed in the conductor layer 50 which is the base layer as compared with the other portion. FIG. 19 illustrates a state where the base layer diameter enlarging step is completed in the portion illustrated in FIG. 18. Furthermore, what is illustrated by the dotted line in FIG. 19 is the initial shape of the inner surface of the recess 151 at the time before the base layer diameter enlarging step is performed.

In this base layer diameter enlarging step, for example, a mixed solution of hydrofluoric acid and nitric acid is used as an etching agent capable of selectively removing the conductor layer 50 made of tungsten. Thus, only a portion of the conductor layer 50 on the inner surface of the recess 151 is selectively removed. As a result, a portion of the recess 151 that is formed in the conductor layer 50 is enlarged as compared with the other portion.

When the base layer diameter enlarging step is performed, apart of a portion of the insulating layer 140, which is the coating layer, that is in contact with the conductor layer 50 which is the base layer is exposed to the inner space of the recess 151. In FIG. 19, the reference numeral “142” is given to the exposed portion. This portion is also referred to below as an “exposed portion 142”.

In this way, the base layer diameter enlarging step performed to form the contact 200 is a step of exposing a part of a portion of the insulating layer 140, which is the coating layer, that is in contact with the conductor layer 50 by enlarging a portion of the recess 151 that is formed in the conductor layer 50 which is the base layer.

<Inner Peripheral Surface Removing Step>

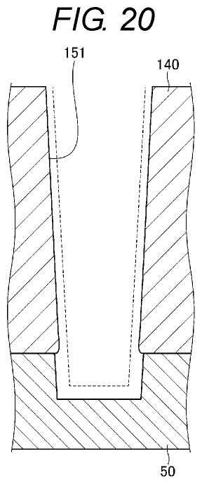

When the base layer diameter enlarging step is completed, the same inner peripheral surface removing step as described with reference to FIG. 13 is performed. The inner peripheral surface removing step is a step performed for cleaning the inner surface of the recess 151. In the inner peripheral surface removing step, wet etching using diluted hydrofluoric acid is performed on the inner surface of the recess 151. FIG. 20 illustrates a state where the inner peripheral surface removing step is completed in the portion illustrated in FIG. 19. Furthermore, what is illustrated by the dotted line in FIG. 20 is the initial shape of the inner surface of the recess 151 at the time before the inner peripheral surface removing step is performed. In this way, the inner peripheral surface removing step is a step of etching the surface of the insulating layer 140 exposed inside the recess 151.

In the inner peripheral surface removing step, the entire inner surface of the recess 151 is exposed to diluted hydrofluoric acid. At this time, in most of the insulating layer 140 which is the coating layer, only a side surface portion exposed toward the recess 151 is exposed to diluted hydrofluoric acid, and this portion is removed. However, as illustrated by the arrows in FIG. 19, in the lowermost portion of the insulating layer 140, not only the side surface portion exposed toward the recess 151 but also the exposed portion 142 on the lower surface side are exposed to diluted hydrofluoric acid. Therefore, in the inner peripheral surface removing step, a portion of the inner peripheral surface of the recess 151 near the lower end portion of the insulating layer 140 is removed more than the other portion.

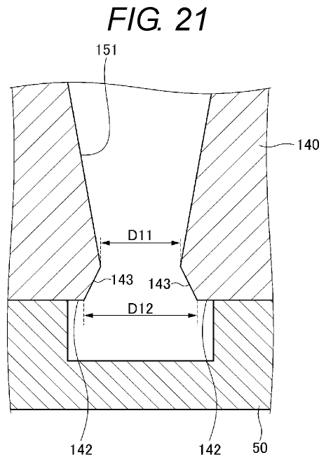

FIG. 21 schematically illustrates the shape of the recess 151 at the time when the inner peripheral surface removing step is completed. As illustrated in FIG. 21, the inner diameter of the recess 151 in the cross section perpendicular to the longitudinal direction of the recess 151 becomes smaller from the upper side to the lower side, and in the smallest portion, this inner diameter becomes D11. However, the inner diameter of the recess 151 becomes larger toward the lower side in a portion on the further lower side of this portion, that is, the portion designated by the reference numeral “143” in FIG. 21, and the inner diameter of the recess 151 becomes D12 larger than D1 at the lower end of the insulating layer 140 which is the coating layer. This is because a portion near the lower end portion of the insulating layer 140 is removed more than the other portion as described above.

In this way, after the third recess forming step is completed, the base layer diameter enlarging step and the inner peripheral surface removing step are sequentially executed. In the base layer diameter enlarging step, the inner diameter of a portion of the recess 151 that is formed in the conductor layer 50 which is the base layer is enlarged, and the exposed portion 142 is formed in the coating layer 140 which is the coating layer. In the subsequent inner peripheral surface removing step, the surface of the coating layer 140 exposed inside the recess 151 is etched, and a portion near the lower end portion of the coating layer 140 is removed more than the other portion. Thus, the inner diameter of the recess 151 is enlarged near the lower end portion of the insulating layer 140 which is the coating layer, so that the distribution of the inner diameter of the recess 151 may be made close to even distribution.

<Conductor Embedding Step>

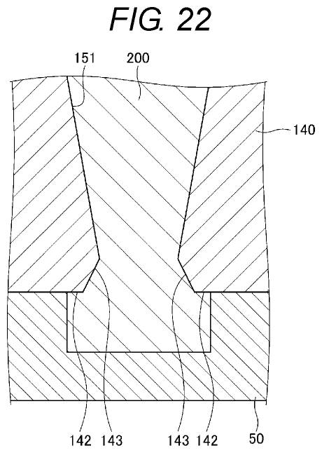

In a conductor embedding step performed after the inner peripheral surface removing step, a conductive material such as tungsten is embedded inside the recess 151 formed as described above, so that the contact 200 is formed. FIG. 22 illustrates a state where the conductor embedding step is completed in the portion illustrated in FIG. 20. Embedding of the conductive material may be performed by, for example, CVD.

As illustrated in FIG. 22, in a portion of the contact 200, near the boundary between the conductor layer 50 and the insulating layer 140 (the portion designated by the reference numeral 143), the shape of the cross section of the contact 200 perpendicular to the longitudinal direction thereof becomes larger as it approaches the above boundary from the insulting layer 140 side (that is, the upper side). As a result, the diameter of the contact 200 in a portion of the contact 200 that penetrates the insulating layer 140 is substantially uniform. Such a contact 200 has the same outer shape as that of the columnar body 100, and may be called a “columnar body” that penetrates the insulating layer 140 and is connected to the conductor layer 50.

As described above, when forming the contact 200, the same method as the method of forming the columnar body 100 may also be used.

This method may also be adopted when forming another columnar body in the semiconductor storage device 10. Examples of the “another columnar body” include support columns that reinforce each insulating layer 140 in a state where the sacrificial layer 60 is removed in the replacement step. The support columns are provided at a plurality of positions to vertically penetrate each conductor layer 50 in, for example, the stepped portion of FIG. 16. Furthermore, the support column has the same structure as the columnar body 100 described above, and is different from the columnar body 100 only in the installation position thereof. Further, the support column is formed at the same time as the columnar body 100 by using the same method as the method of forming the columnar body 100. Therefore, a specific method of forming the support column is omitted.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a base layer;
a coating layer covering the base layer; and
a columnar body extending into the coating layer and connected to the base layer,
wherein, along a longitudinal direction of the columnar body extending from a boundary between the base layer and the coating layer, a cross section of the columnar body perpendicular to the longitudinal direction has a width that becomes smaller for a distance.

2. The semiconductor storage device according to claim 1, wherein the cross section of the columnar body has a width that becomes smaller from an upper end of the columnar body in a direction towards the boundary between the base layer and the coating layer.

3. The semiconductor storage device according to claim 2, wherein the cross section of the columnar body has a width that continuously becomes smaller from an upper end of the columnar body to some predetermined point, at which the width of the cross section of the columnar body then becomes larger toward the boundary between the base layer and the coating layer.

4. The semiconductor storage device according to claim 1, wherein the coating layer includes a plurality of insulating layers and a plurality of conductor layers that are alternately stacked on the semiconductor layer.

5. The semiconductor storage device according to claim 1, wherein the columnar body has a semiconductor portion and a memory film.

6. The semiconductor storage device according to claim 5, wherein the semiconductor portion occupies a majority of the columnar body and is formed of a material made of amorphous silicon.

7. The semiconductor storage device according to claim 5, the memory film covers the entire side surface of the semiconductor.

8. A method of manufacturing a semiconductor storage device comprising:
forming a coating layer covering a base layer;
forming a recess that penetrates the coating layer and into the base layer;
enlarging a portion of the recess to expose a portion of the coating layer in contact with the base layer; and
etching a surface of the coating layer exposed inside the recess.

9. The method according to claim 8, wherein the base layer is formed of a material containing silicon.

10. The method according to claim 9, wherein exposing the part of the portion of the coating layer includes enlarging the portion of the recess that is formed in the base layer by etching using a choline aqueous solution.

11. The method according to claim 8, further comprising
removing an inner peripheral surface of the recess by removing a portion of the inner peripheral surface of the recess at a lower end portion of the coating layer more than another portion of the coating layer.

12. The method according to claim 11, wherein the inner peripheral surface of the recess is removed by wet etching or Reactive Ion Etching (RIE) using diluted hydrofluoric acid.

13. The method according to claim 11, wherein the inner peripheral surface of the recess is removed so that an inner diameter of the recess in a cross section perpendicular to a longitudinal direction of the recess becomes smaller from an upper side of the coating layer to a lower side of the coating layer.

14. The method according to claim 13, wherein the inner peripheral surface of the recess is removed so that from a cross section of the recess having a smallest inner diameter thereof, the inner diameter of the recess becomes larger toward a lower end of the coating layer in the longitudinal direction.

15. The method according to claim 11, further comprising:
after removing the inner peripheral surface of the recess, forming a columnar body in the recess.

16. The method according to claim 15, wherein forming the columnar body in the recess includes:
forming a memory film on an inner peripheral surface of the recess; and
forming a semiconductor inside the memory film.

17. The method according to claim 11, wherein
the coating layer includes a plurality of insulating layers and a plurality of sacrificial layers that are alternately formed, and
the method further comprises:
replacing the plurality of sacrificial layers with a plurality of conductor layers.

18. The method according to claim 17, wherein replacing the plurality of sacrificial layers with the plurality of conductor layers includes:
forming slits so as to divide the entirety of the alternately formed insulating layers and sacrificial layers;
removing all of the sacrificial layers by wet etching through the slits; and
forming the conductor layers in a space where the sacrificial layers are formed.
